(19) United States
(12) Patent Application Publication
(10) Pub. No.: US 2016/0155630 A1
(43) Pub. Date: Jun. 2, 2016

(54) SUBSTRATE PROCESSING APPARATUS, METHOD FOR MANUFACTURING SEMICONDUCTOR DEVICE, AND RECORDING MEDIUM

(71) Applicant: HITACHI KOKUSAI ELECTRIC INC., Tokyo (JP)

(72) Inventors: Yasutoshi TSUBOTA, Toyama-shi (JP); Shin HIYAMA, Toyama-shi (JP); Yuichi WADA, Toyama-shi (JP); Kenji KAMEDA, Toyama-shi (JP)

(73) Assignee: HITACHI KOKUSAI ELECTRIC INC., Tokyo (JP)

(21) Appl. No.: 15/007,513

(22) Filed: Jan. 27, 2016

Related U.S. Application Data
(63) Continuation of application No. PCT/JP2014/069701, filed on Jul. 25, 2014.

(30) Foreign Application Priority Data
Jul. 29, 2013 (JP) 2013-156958

(51) Int. Cl. H01L 21/02; H01L 21/67; H01L 21/311

(52) U.S. Cl. CPC H01L 21/02068; H01L 21/311; H01L 21/67069

(57) ABSTRACT

A method for manufacturing a semiconductor device includes: supplying a remover to a substrate including a Si-containing film on which a denatured layer is formed in order to remove the denatured layer; supplying a processing gas containing two or more halogen elements to the substrate in order to remove the Si-containing film; and supplying the remover to the substrate after the act of removing the Si-containing film in order to remove a residue of the denatured layer left after the act of removing the Si-containing film.

### CROSS-REFERENCE TO RELATED APPLICATIONS

This application is a Continuation Application of PCT International Application No. PCT/JP2014/069701, filed on Jul. 25, 2014, which claimed the benefit of Japanese Patent Application No. 2013-156958, filed on Jul. 29, 2013, the entire content of which is hereby incorporated by reference.

### TECHNICAL FIELD

The present disclosure relates to a substrate processing apparatus, a method for manufacturing a semiconductor device, and a recording medium.

### BACKGROUND

With a decrease in size of large scale integrated circuits (LSIs), patterning techniques have been accordingly sophisticated. Wet etching with chemicals is being mainly used for patterning.

However, the minimum feature size of semiconductor devices represented by recent LSIs, DRAMs (Dynamic Random Access Memory) or flash memories is smaller than 30 nm wide. Wet etching, which is one of the steps in a process for manufacturing such semiconductor devices, has the following problem. For example, there is a pattern collapse caused by a surface tension of liquid used in wet etching. This makes it difficult to achieve miniaturization and a high manufacturing throughput of semiconductor devices while keeping the quality thereof.

The present disclosure provides some embodiments of a substrate processing apparatus which is capable of increasing a manufacturing throughput of semiconductor devices while improving the quality thereof, a method for manufacturing a semiconductor device, and a recording medium.

### SUMMARY

According to one embodiment of the present disclosure, there is provided a method for manufacturing a semiconductor device, including: supplying a remover to a substrate including an Si-containing film on which a denatured layer is formed in order to remove the denatured layer; supplying a processing gas containing two or more halogen elements to the substrate in order to remove the Si-containing film; and supplying the remover to the substrate after the act of removing the Si-containing film in order to remove a residue of the denatured layer left after the act of removing the Si-containing film.

According to another embodiment of the present disclosure, there is provided a substrate processing apparatus including: a processing vessel configured to accommodate a substrate including a Si-containing film on which a denatured layer is formed; a remover supplying part configured to supply a remover of the denatured layer to the substrate; a processing gas supplying part configured to supply a processing gas capable of removing the Si-containing film and containing two or more halogen elements to the substrate; and a control unit configured to control the remover supplying part and the processing gas supplying part to perform a process including: supplying the remover through the remover supplying part to the substrate, supplying the processing gas through the processing gas supplying part to the substrate, and supplying the remover through the remover supplying part to the substrate after the act of supplying the processing gas to the substrate, and wherein the control unit is connected to flow rate controllers and on-off valves for control of supply amounts of the remover and the processing gas.

According to another embodiment of the present disclosure, there is provided a non-transitory computer-readable recording medium storing a program that causes a computer to perforin a process of: supplying a remover to a substrate including Si-containing film on which a denatured layer is formed in order to remove the denatured layer; supplying a processing gas containing two or more halogen elements to the substrate in order to remove the Si-containing film; and supplying the remover to the substrate after the act of removing the Si-containing film in order to remove a residue of the denatured layer left after the act of removing the Si-containing film

### BRIEF DESCRIPTION OF THE DRAWINGS

FIG. 1 shows a configuration example of a substrate processing apparatus according to one embodiment of the present disclosure.

FIG. 2A shows a configuration example of a substrate before being processed, according to one embodiment of the present disclosure.

FIG. 2B shows another configuration example of the substrate before being processed, according to one embodiment of the present disclosure.

FIG. 2C shows still another configuration example of the substrate before being processed, according to one embodiment of the present disclosure.

FIG. 3 is a side cross-sectional view of a configuration example of a transfer system according to one embodiment of the present disclosure.

FIG. 4 is a top cross-sectional view of the configuration example of the transfer system according to one embodiment of the present disclosure.

FIG. 5 shows a structural example of a controller according to one embodiment of the present disclosure.

FIG. 6 shows an example of a substrate processing flow according to one embodiment of the present disclosure.

FIG. 7 is a conceptual view in which a silicon oxide film is left as a residue.

FIG. 8A illustrates an example of substrate processing according to one embodiment of the present disclosure.

FIG. 8B illustrates another example of substrate processing according to one embodiment of the present disclosure.

### DETAILED DESCRIPTION

Some embodiments of the present disclosure will now be described.

The present inventors have found that a Si-containing film consisting mainly of an Si element at least for silicon oxide (SiO₂), silicon nitride (Si₃N₄), titanium nitride (TiN) and amorphous carbon (a-C) could be selectively removed in a certain temperature range by performing a dry etching process using a processing gas to be described later. In addition, it has been found that the Si-containing film could be isotropically removed by using the processing gas to be described later without plasmarizing the processing gas. The term “Si-containing film” used herein refers to a film containing an Si element by 90% or more.

### First Embodiment

Hereinafter, an embodiment of the present disclosure will be described in more detail with reference to the drawings.

### (1) Configuration of Substrate Processing Apparatus

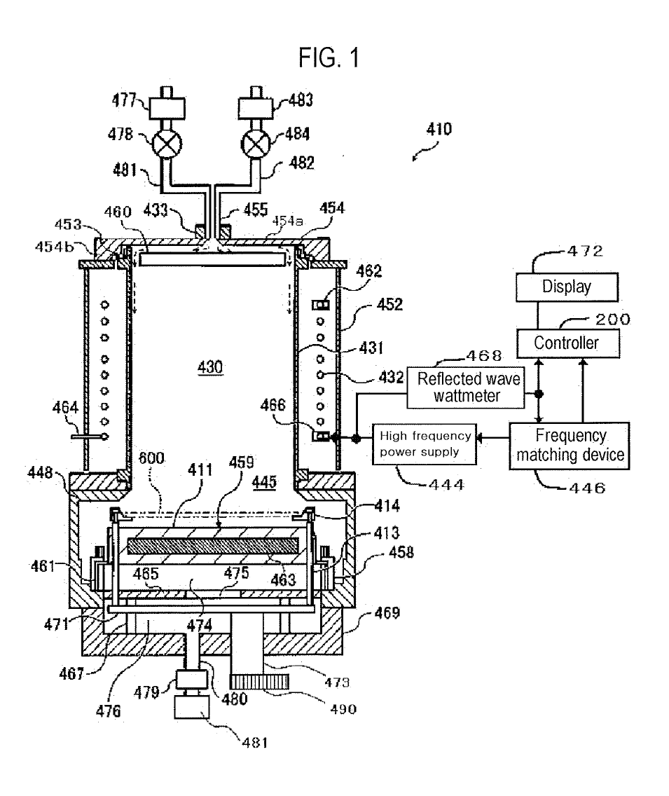

First, the configuration of a substrate processing apparatus according to this embodiment will be mainly described with reference to FIG. 1. FIG. 1 is a schematic view showing a configuration example of the substrate processing apparatus according to this embodiment, in which a processing furnace 202 is shown in a longitudinal sectional view.

### (Substrate)

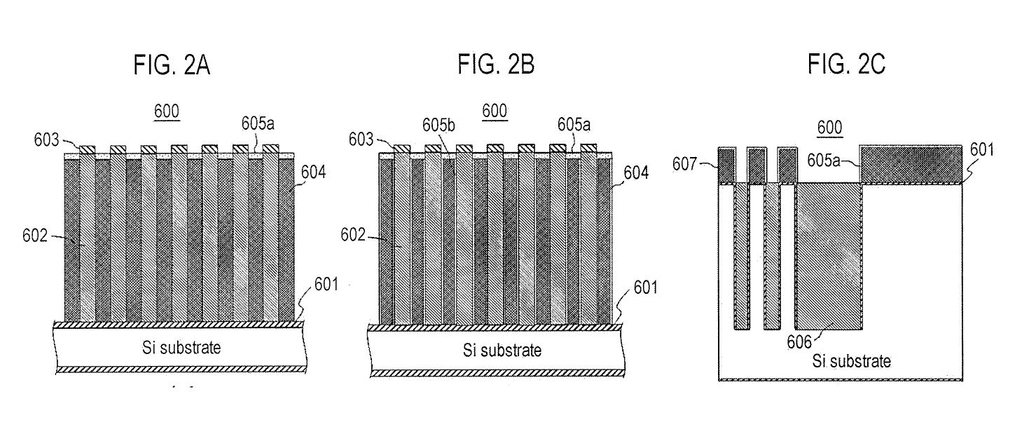

For example, as shown in FIG. 2A, a silicon nitride film 601 as a stopper film, a titanium nitride film 602 as a cylindrical electrode, a silicon nitride film 603 as a collapse prevention support part of the electrode, a silicon-containing film 604, and a denatured layer 605a on the silicon-containing film 604 are formed in a wafer 600 as a substrate. The silicon-containing film 604 is a mold silicon film for formation of the electrode and is removed during a silicon-containing film removing process. An example of the mold silicon film may include amorphous silicon, poly-silicon, doped silicon, single crystal silicon or the like. For example, the denatured layer 605a is a silicon oxide film formed when oxygen is adsorbed or diffused into the surface and upper portion of the mold silicon film. FIG. 2B illustrates a case where a denatured layer (interface denatured layer 605b) formed by oxidation of the silicon-containing film 604 exists in an interface between the silicon-containing film 604 and the titanium nitride film 602. In this case, the interface denatured layer 605b is left after the silicon-containing film 604 is removed. In this way, the interface denatured layer 605b left after the removal of the mold silicon-containing film may remain. FIG. 2C shows another example where a silicon hard mask 607, which is a film to be removed, a denatured layer 605a, an SOC (Spin On Carbon) film 606 as a buried film, and a silicon nitride film (or silicon oxide film) 601 as a stopper film covering a silicon substrate surface are forming. An example of the silicon hard mask 607 may include amorphous silicon, poly-silicon, doped silicon or the like. It is assumed in this example that the denatured layer 605 of the surface of the silicon-containing film is generated when the surface of the silicon hard mask 607 is denatured in natural oxidation of the surface of the silicon hard mask 607, a dry etching process of patterning the silicon hard mask 607 or a resist film removing process. The present inventors have developed a selective substrate processing for removing a silicon-containing film, through a combination of denatured layer removing process and silicon-containing film removing process, as will be described later, for a substrate as shown in FIGS. 2A to 2C.

### (Process Chamber)

A processing vessel 431 is typically made of non-metallic material such as quartz glass or ceramics and is formed in a cylindrical shape. However, this may be made of metallic material unless otherwise required. The top of the processing vessel 431 is blocked by a top plate 454 and the bottom thereof is blocked by a level base plate 448 as a stand and a bottom board 469. Further, the processing vessel 431 is air-tightly sealed by a pressure adjusting mechanism to be described later. The upper internal space of the processing vessel 431 serves as a gas mixing chamber 430. The gas mixing chamber 430 is optimized according to desired gas flow and mixing conditions. In addition, the gas mixing chamber 430 may be provided therein with a shower plate through which a gas can be directly supplied into a process chamber 445 to be described later. In addition, a space formed in the lower side of the base plate 448, in which a wafer 600 is placed, serves as the process chamber 445. In addition, in a case where plasma is used to remove a silicon oxide film, the upper internal space of the processing vessel 431 serves as a gas mixing chamber 430 and plasma is generated in a space facing a resonance coil 432 serving as an excitation part, which will be described later.

### (Substrate Support Part)

A susceptor 459 is installed on the bottom of the process chamber 445. The susceptor 459 includes a susceptor table 411 and a substrate heating part 463 for keeping a wafer on the susceptor at a predetermined temperature. In addition, the substrate heating part 463 may include a cooling mechanism for eliminating excessive heat, if necessary. In addition, the susceptor 459 has a structure supported by a plurality of posts 461. A plurality of lifter pins 413 is provided to extend through the susceptor table 411. A plurality of corresponding wafer support pins 414 is provided on the plurality of lifter pins 413. The wafer support pins 414 extend toward the center of the susceptor 459. The wafer 600 is mounted on the susceptor table 411 or the wafer support pins 414. Although it is shown that the wafer support pins 414 have a structure to support the periphery of the wafer 600, these pins 414 may have a structure to support the vicinity of the center of the wafer 600, if necessary. When the vicinity of the center of a substrate is supported, it is possible to alleviate substrate bending, which may occur when a large-diameter substrate such as a 450 mm-diameter substrate is supported, and to improve processing uniformity. For example, if a substrate has a bent portion, a gas flow and wafer temperature in the vicinity of the bent portion may be different from a gas flow and wafer temperature in portions other than the bent portion, which may cause a change in processing uniformity. A substrate support part is composed of the wafer support pins 414. In some cases, the substrate support part may be considered to include the susceptor table 411 and the lifter pins 413. The lifter pins 413 are connected to a lifting board 471 and are configured to be lift by a lifting driver 490 along a guide shaft 467.

### (Exhaust Part)

An exhaust part is disposed below the susceptor 459. The exhaust part includes an APC (Auto Pressure Control) valve 479 as a pressure adjusting part (pressure adjusting mechanism), and an exhaust pipe 480. In some cases, an exhaust pump 481 may be included in the exhaust part. A degree of valve opening of the APC valve 479 is configured to be feedback-controlled based on the internal pressure of the process chamber 445. The internal pressure of the process chamber 445 is measured by a pressure sensor (not shown). A halogen-containing gas used in this embodiment is heavier than a nitrogen (N₂) gas which is typically used as a purge gas. For example, an iodine heptafluoride (IF₇) gas, which will be described later, has a specific gravity of about 2.7 at room temperature and is about 2.8 times as heavy as the nitrogen (N₂) gas. Therefore, forming an exhaust port in the lower portion of the process chamber where the halogen-containing gas can easily stay is useful for inhibiting the halogen-containing gas from remaining in the process chamber. In addition, in order to promote discharge of the halogen-containing gas, it may be configured so that a purge gas can be supplied into the exhaust part.

### (Baffle Ring)

In addition, a cylindrical baffle ring 458 and an exhaust plate 465 may be disposed to improve a flow of processing gas. A number of vent holes are evenly formed in the cylindrical side of the baffle ring 458 and an exhaust communicating hole 475 is formed in the central portion of the exhaust plate 465. A first exhaust chamber 474 is formed by the susceptor 459, the baffle ring 458 and the exhaust plate 465 and a second exhaust chamber 476 is formed by the exhaust plate 465 and the bottom board 469. The first exhaust chamber 474 and the second exhaust chamber 476 communicate to each other by the exhaust communicating hole 475. In addition, the exhaust pipe 480 communicates to the second exhaust chamber 476. When the first exhaust chamber 474 and the second exhaust chamber 476 are separately provided as above, it is possible to achieve uniform exhaust from the entire circumferential direction of the wafer 600, which results in uniform processing uniformity of the wafer 600.

### (Gas Supply Part)

In the top plate 454 of the processing vessel 431, a gas supply pipe 455 for supplying a plurality of required processing gases from gas supply equipment (not shown) is attached to a gas inlet 433. The gas supply pipe 455 is provided with a processing gas supply part for supplying a halogen element-containing gas as a processing gas into the substrate, a remover supply part for supplying a remover to the substrate, and a third supply part (not shown) for supplying other gas (such as an N₂ gas for purge or a chlorine fluoride (ClF₃) gas for cleaning), as needed. An example of the remover used may include a hydrogen fluoride gas or the like. Although it is shown that the remover is supplied in the form of a gas, the present disclosure is not limited thereto. For example, the remover may be in the form of a liquid for removal by etching. If a denatured layer is to be removed with sputtering, a rare gas such as argon may be used. The gas supply parts are respectively provided with mass flow controllers 477 and 483 as flow rate controllers, and on-off valves 478 and 484 for control of a supply amount of gas. Although only the processing gas supply part and the remover supply part are shown, the third and subsequent gas supply parts may be provided. In addition, the gases to be used may be mixed in advance before they are flown into the gas inlet 433. In addition, in order to adjust a flow of processing gas, a cylindrical baffle plate 460 made of quartz glass or ceramics is installed within the processing vessel 431. In addition, a shower plate may be employed as needed. When the supply amount and exhaust amount of gas are adjusted by the flow rate controllers and the APC valve 479, the internal pressures of the processing vessel 431 and the process chamber 445 are controlled to their respective desired values.

### (Excitation Part)

If plasma is used to remove the denatured layer, an excitation part for generating the plasma may be provided. The resonance coil 432 serving as the excitation part has a winding diameter, a winding pitch and a winding number, which are set to allow the resonance coil 432 to be resonated in a certain wavelength mode in order to form a standing wave having a specified wavelength. That is, an electrical length of the resonance coil 432 is set to a length equivalent to an integral multiple (one time, two times, . . . ) of one wavelength, a half wavelength or a ¼ wavelength for a specified frequency of power supplied from a high frequency power supply 444. For example, for 27.12 MHz, the length of one wavelength is about 11 meters. The frequency and resonance coil length used may be appropriately selected depending on a desired plasma generation condition, mechanical dimension of the gas mixing chamber 430, etc.

More specifically, in consideration of applied power, the intensity of a generated magnetic field, the external form of an applied apparatus or the like, the resonance coil 432 is formed with an effective sectional area of 50 to 300 mm² and a coil diameter of 200 to 500 mm, for example so that a magnetic field of 0.01 to 10 Gauss or so can be generated by high frequency power of 0.5 to 5 kW at 800 kMz to 50 MHz, and is wound 2 to 60 times around the periphery of the processing vessel 431. The resonance coil 432 is made of copper pipe, copper sheet, aluminum pipe, aluminum sheet, a material obtained by depositing a copper plate or aluminum on a polymer belt, or the like. The resonance coil 432 is supported by a plurality of plate-like insulating supports which are vertically erected on the top surface of the base plate 448.

Both ends of the resonance coil 432 are electrically grounded. At least one end of the resonance coil 432 is grounded via an operation tap 462 in order to finely adjust the electrical length of the resonance coil when the apparatus is first installed or when process conditions are changed. For example, the resonance coil 432 is grounded by a fixed ground point 464. In order to finely adjust the impedance of the resonance coil 432 when the apparatus is first installed or when process conditions are changed, a power feeder is constituted by an operation tap 466 between both grounded ends of the resonance coil 432.

That is, the resonance coil 432 includes electrically-grounded ground portions at both ends, and the power feeder which receives power from the high frequency power supply 444 is interposed between the ground portions. At least one of the ground portions is a position-adjustable variable ground portion, and the power feeder may be a position-adjustable variable power feeder. When the resonance coil 432 includes the variable ground portion and the variable power feeder, it is possible to adjust the resonance frequency and load impedance of the gas mixing chamber 430 even more simply, as will be described later.

In addition, a waveform adjusting circuit composed of a coil and a shield may be inserted in one end (or both ends) of the resonance coil 432, such that currents opposite to each other in phase can be flown into an object with respect to an electrical middle point of the resonance coil 432. Such a waveform adjusting circuit is configured as an open circuit by making the end portions of the resonance coil 432 electrically insulated from each other or electrically equivalent to each other. In addition, the end portions of the resonance coil 432 may be non-grounded by chock series resistance and may be DC-coupled to a fixed reference voltage.

An outer shield 452 is provided to shield an electromagnetic wave leaked to the outside of the resonance coil 432 and form a capacitive component which is required to form a resonance circuit between the outer shield 452 and the resonance coil 432. The outer shield 452 is generally made of a conductive material such as an aluminum alloy, copper, a copper alloy or the like and is formed in a cylindrical shape. The outer shield 452 is disposed at a distance, for example, by about 5 to about 10 mm, from the periphery of the resonance coil 432. Typically, the outer shield 452 is grounded to make its potential equal to the potential of both ends of the resonance coil 432. In order to correctly set the resonance frequency of the resonance coil 432, one end or both ends of the outer shield 452 may be made to provide an adjustable tap position or trimming capacitance may be inserted between the resonance coil 432 and the outer shield 452. In addition, a spiral resonator is constituted by the electrically-grounded outer shield 452 and the resonance coil.

The high frequency power supply 444 may be a high frequency generator or any other appropriate power supply as long as it can supply power having a required voltage and frequency to the resonance coil 432. For example, the high frequency power supply 444 may be a power supply capable of supplying power of about 0.5 to about 5 kW at 80 kHz to 800 MHz.

In addition, a reflected wave wattmeter 468 is disposed at the output side of the high frequency power supply 444. Reflected wave power detected by the reflected wave wattmeter 468 is input to a controller 500 used as a control unit. The controller 500 controls not only the high frequency power supply 444 but also the overall operation of various components of the substrate processing apparatus, including, for example, a substrate transfer mechanism and a gate valve. A display 472 as a display device displays data detected by various detectors installed in the substrate processing apparatus, such as results of detection of a reflected wave by the reflected wave wattmeter 468. In addition, a frequency matching device 446 for controlling an oscillation frequency is connected to the high frequency power supply 444.

In this embodiment, the excitation part is constituted by the resonance coil 432 and may be considered to include one or more of the high frequency power supply 444, the outer shield 452, the reflected wave wattmeter 468 and the frequency matching device 446.

### (Substrate Transfer System)

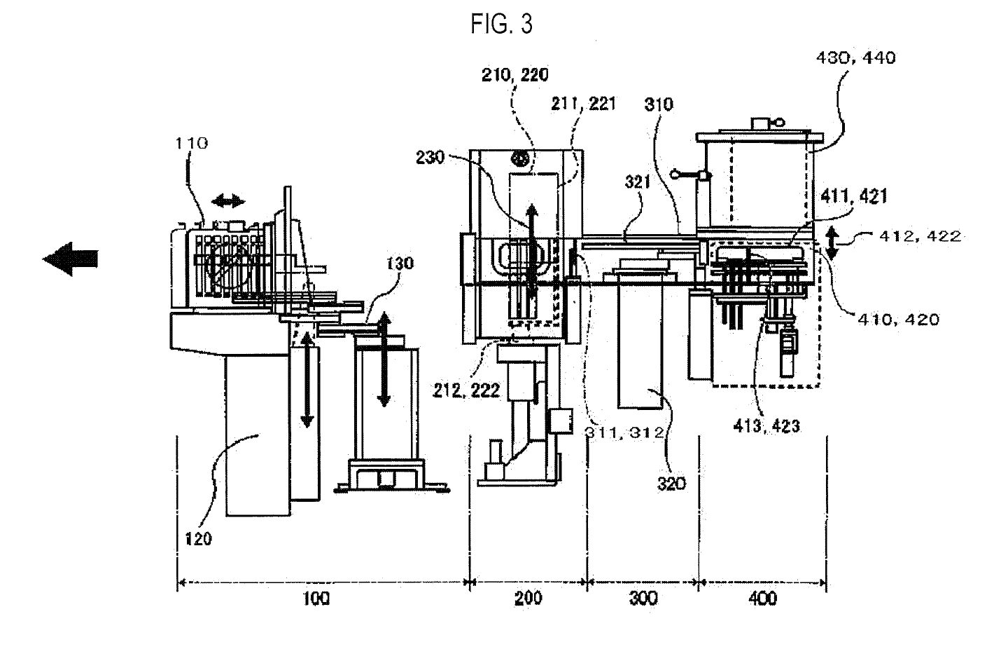

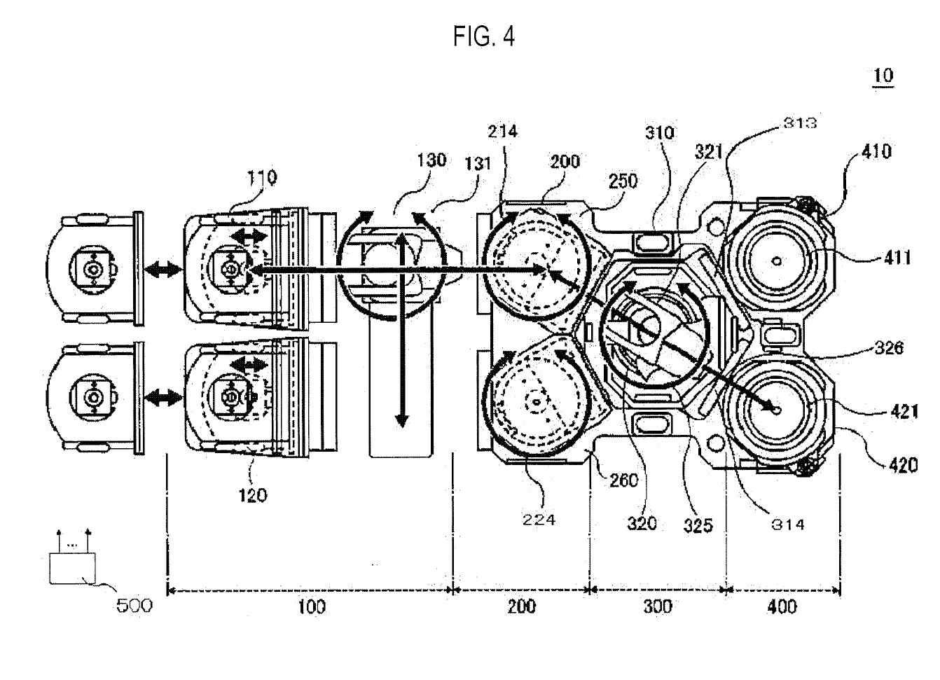

Next, a substrate transfer system in this embodiment will be described with reference to FIGS. 3 and 4. The substrate transfer system includes an EFEM (Equipment Front End Module) 100, a load lock chamber part 200 and a transfer module part 300.

The EFEM 100 includes FOUPs (Front Opening Unified Pods) 110 and 120 and an atmosphere transfer robot 130 as a first transfer part for transferring wafers from the FOUPs to respective load lock chambers. 25 wafers are loaded on each FOUP and an arm of the atmosphere transfer robot 130 takes five wafers at a time out of the FOUP. The interior of the EFEM 100 and the interiors of the FOUPs 110 and 120 may be placed under an inert gas atmosphere in order to suppress natural oxidation of the wafers, as necessary.

The load lock chamber part 200 includes load lock chambers 250 and 260 and buffer units 210 and 220 for holding the wafers, which are transferred from the FOUPs, in the respective load lock chambers 250 and 260. The buffer units 210 and 220 include respective boats 211 and 221 and respective index assemblies 212 and 222 lying thereunder. The boats 211 and 221 and the underlying index assemblies 212 and 222 are simultaneously rotated by respective θ axes 214 and 224. In addition, the interior of the load lock chamber part 200 may be placed under a vacuum atmosphere, an inert gas atmosphere or a reduced-pressure atmosphere where an inert gas is supplied.

The transfer module part 300 includes a transfer module 310 used as a transfer chamber. The above-described load lock chambers 250 and 260 are attached to the transfer module 310 via gate valves 311 and 312, respectively. A vacuum art robot unit 320 used as a second transfer part is installed in the transfer module 310. The transfer module part 300 may be placed under a vacuum atmosphere, an inert gas atmosphere or a reduced-pressure atmosphere where an inert gas is supplied. In order to suppress unexpected adsorption of oxygen onto the wafers 600 while improving a transfer throughput of the wafers 600, it is preferable to place the interiors of the load lock chamber part 200 and the transfer module part 300 under a reduced-pressure atmosphere where an inert gas is supplied.

A process chamber part 400 includes process chambers 410 and 420 and gas mixing chambers 430 and 440 disposed thereon. The process chambers 410 and 420 are attached to the transfer module 310 via gate valves 313 and 314, respectively. In this embodiment, the process chambers 410 and 420 have the same configuration.

### (Controller)

The controller controls the above-described various parts to perform a substrate processing process to be described later.

### (Control Part)

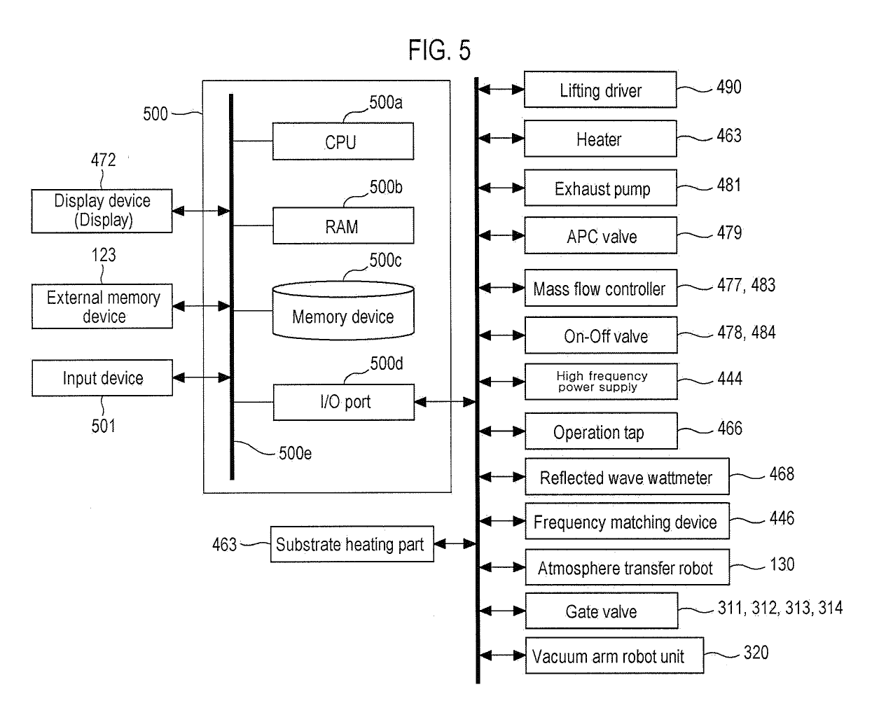

As shown in FIG. 5, the controller 500 serving as a control part (control means) is configured as a computer including a CPU (Central Processing Unit) 500a, a RAM (Random Access Memory) 500b, a memory device 500c and an I/O port 500d. The RAM 500b, the memory device 500c and the I/O port 500d are configured to exchange data with the CPU 500a via an internal bus 500e. An input/output device 501 configured as, for example, a touch panel or the like, is connected to the controller 500.

The memory device 500c is configured with, for example, a flash memory, an HDD (Hard Disk Drive), or the like. A control program for controlling operations of the substrate processing apparatus and a process recipe in which a sequence or condition for substrate processing to be described later is written are readably stored in the memory device 500c. The process recipe, which is a combination of sequences, causes the controller 500 to execute each sequence in a substrate processing process to be described later in order to obtain a predetermined result, and functions as a program. Hereinafter, the process recipe and the control program may be collectively referred to as a program. When the term “program” is used herein, it may include a case in which only one of the process recipe and the control program is included, or a case in which any combination of the process recipe and the control program is included. The RAM 500b is configured as a memory area (work area) in which a program or data read by the CPU 500a is temporarily stored.

The I/O port 500d is connected to the above-described lifting driver 490, substrate heating part 463, APC valve 479, mass flow controllers 477 and 483, on-off valves 478 to 484, exhaust pump 481, atmosphere transfer robot 130, gate valves 313 and 314, vacuum arm robot unit 320, and so on. In addition, when the excitation part is provided, the I/O port 500d is connected to the high frequency power supply 444, the operation tap 466, the reflected wave wattmeter 468 and the frequency matching device 446.

The CPU 500a is configured to read and execute the control program from the memory device 500c. According to an input of an operation command from the input/output device 501, the CPU 500a reads the process recipe from the memory device 500c. The CPU 500a is configured to control the lifting up/down operation of the lifter pins 413 by the lifting driver 490, the heating/cooling operation of the wafer 600 by the substrate heating part 463, the pressure adjusting operation by the APC valve 479, the processing gas flow rate operation by the mass flow controllers 477 and 483 and the on-off valves 478 and 484, and the like according to contents of the read process recipe.

The controller 500 is not limited to being configured as a dedicated computer but may be configured as a general-purpose computer. For example, the controller 500 of this embodiment may be configured by preparing an external memory device 123 (for example, a magnetic tape, a magnetic disc such as a flexible disc or a hard disk, an optical disc such as a CD or DVD, a magneto-optical disc such as an MO, a semiconductor memory such as a USB memory or a memory card), in which the program is stored, and installing the program on the general-purpose computer using the external memory device 123. However, a means for supplying a program to a computer is not limited to the case in which the program is supplied through the external memory device 123. For example, the program may be supplied using a communication means such as the Internet or a dedicated line, rather than through the external memory device 123. The memory device 500c or the external memory device 123 is configured as a non-transitory computer-readable recording medium. Hereinafter, these means for supplying the program will be simply referred to as “a recording medium.” When the term “recording medium” is used herein, it may include a case in which only the memory device 500c is included, a case in which only the external memory device 123 is included, or a case in which both the memory device 500c and the external memory device 123 are included.

### (2) Substrate Processing Process

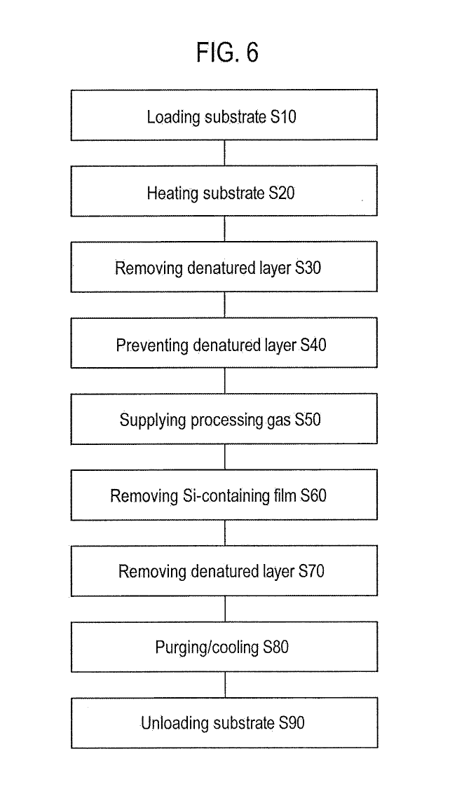

Subsequently, a substrate processing process performed as one process of a method for manufacturing a semiconductor device according to this embodiment will be described with reference to FIG. 6. This process is performed by the above-described substrate processing apparatus. In the description, operations of various parts constituting the substrate processing apparatus are controlled by the controller 500.

### (Substrate Loading Step S10)

First, a wafer 600 is transferred from the FOUP 110 into the load lock chamber 250 by the atmosphere transfer robot 130. In the load lock chamber 250, evacuation is performed to substitute the internal air atmosphere or inert gas atmosphere of EFEM with a vacuum atmosphere, an inert gas atmosphere or a reduced-pressure atmosphere where an inert gas is supplied. When the atmosphere substitution is completed, the gate valve 311 interposed between the load lock chamber 250 and the transfer module 310 is opened, and the wafer 600 is transferred from the load lock chamber 250 into the transfer module 310 by the vacuum arm robot unit 320. After the wafer 600 is transferred, the gate valve 311 is closed. Thereafter, the wafer 600 is mounted on the wafer support pins 414 on the lifter pins 413 through the gate valve 313 interposed between the transfer module 310 and the process chamber 410. After the wafer transfer mechanism is retracted outside of the process chamber 445, the gate valve 313 is closed. When the wafer 600 is transferred, it is preferable in some embodiments to purge a transfer path with an inert gas and transfer the wafer 600 in a reduced-pressure state. When the wafer 600 is transferred under the inert gas atmosphere in the reduced-pressure state, it is possible to suppress oxidation (oxygen adsorption) of a semiconductor device formed on the wafer 600 and unintended adsorption of water onto the semiconductor device.

### (Substrate Heating Step S20)

Next, the lifter pins 413 are lifted down to mount the wafer 600 on the susceptor table 411. Here, the lifter pins 413 are lifted up/down by the lifting driver 490. The substrate heating part 463 included in the susceptor 459 is already heated to a predetermined temperature in order to heat the wafer 600 to a predetermined wafer temperature, e.g., room temperature or low temperature or so. If necessary, a cooling mechanism may be also used to eliminate excessive heat (heat of reaction). Here, a low temperature refers to a temperature range in which a removal gas or a processing gas described later is sufficiently vaporized and a temperature at which characteristics of a film formed on the wafer 600 is not changed in quality.

### (Denatured Layer Removing Step S30)

Subsequently, a denatured layer is removed from the wafer 600 by supplying a removal gas as a predetermined remover from the gas supply pipe 455 to the wafer 600. The removal of the denatured layer is performed by supplying the remover to the wafer 600. For example, the removal of the denatured layer is performed by supplying a removal gas. An example of the removal gas may include an HF gas. A flow rate of the removal gas is set to fall within a range of 0.1 slm to 10 slm, and in some embodiments, 3 slm. The internal pressure of the process chamber is set to fall within a range of 1 Pa to 1300 Pa, and in some embodiments, 100 Pa. The HF gas may be used to remove a silicon nitride film, although it is particularly effective in removing a silicon oxide film. In this case, the HF gas may be introduced in the process chamber or, alternatively, an HF gas component may be generated by introducing a mixture of an IF₇ gas and a hydrogen (H₂) gas in the process chamber and plasmarizing the mixture. The supply of the IF₇ gas makes it possible to perform preliminary processing of a Si-containing film removing step to be described later. That is, it is possible to remove an intermediate layer between the denatured layer and a silicon-containing film and more reliably remove the silicon-containing film in the silicon-containing film removing step. Although it is here illustrated that the denatured layer is removed with the HF gas, the present disclosure is not limited thereto. For example, a reducing gas may be used to remove oxygen. An example of the reducing gas may include a hydrogen (H₂) gas. In addition, if an amount of adsorption of oxygen onto a surface by a cleaning solution or the like falls within an allowable range, the denatured layer may be removed with a wet etching process using a removal solution (e.g., an HF aqueous solution) as a remover. Alternatively, the denatured layer may be removed by supplying a gas, which is obtained by activating (plasmarizing) one or both of a rare gas such as an argon (Ar) gas and a reducing gas such as a hydrogen gas, as a remover, to the wafer 600. The denatured layer can be removed with sputtering by supplying the activated rare gas to the wafer 600. In addition, the denatured layer can be deoxidized by supplying the activated hydrogen gas to the wafer 600. By supplying such an activated remover (e.g., the activated Ar gas) to the wafer 600, it is possible to remove the denatured layer 605a without doing damage to the SOC film 606 as a buried film, as compared to the case where the HF gas is used. That is, it is possible to remove the denatured layer 605a without impairing the function as the buried layer.

After the denatured layer is removed, it is preferable to perform purging required in preparation for the new next step.

### (Denatured Layer Preventing Step S40)

This step is to prevent a denatured layer from being grown again after the earlier-described denatured layer is removed. For example, a denatured layer is prevented from occurring by keeping the wafer 600 under an inert gas atmosphere, a reducing atmosphere or a vacuum atmosphere. In this embodiment, since a series of processes is performed in the same process chamber, it is possible to quickly shift to the next step without mixing oxygen in the atmosphere of the process chamber.

### (Processing Gas Supplying Step S50)

Subsequently, a predetermined processing gas is supplied from the gas supply pipe 455. The process gas supplied may be a halogen-containing gas as an etching gas, an inert gas for purge or dilution, or the like. Here, the halogen-containing gas is a gas containing two or more halogen elements of fluorine (F), chlorine (Cl), bromine (Br) and iodine (I), such as iodine pentafluoride (IF₅), iodine heptafluoride (IF₇), bromine trifluoride (BrF₃), bromine pentafluoride (BrF₅), xenon difluoride (XeF₂) or chlorine trifluoride (ClF₃). In this embodiment, the halogen-containing gas may be IF₇. IF₇ can remove a silicon-containing film actively (selectively). The term “selectively” used herein refers to making an etching rate of the silicon-containing film larger than an etching rate of a different film (e.g., a metal film). The inert gas may be not only a nitrogen (N₂) gas but also a rare gas such as He, Ne, Ar or the like.

At the same time of supplying the gas, an exhaust volume of the gas is adjusted by the APC valve 479 such that the entire internal pressure of the process chamber 445 is maintained at a specified pressure (e.g., 100 Pa) within a range of 1 to 1330 Pa and a partial pressure of IF₇ is maintained at a specified pressure (e.g., 100 Pa) within a range of 1 to 1330 Pa. A flow rate of the gas is set to a specified value (e.g., 3 SLM) within a range of 0.1 to 10 SLM. In addition, as necessary, after the atmospheres of the processing vessel 431 and the process chamber 445 are once exhausted, the specified gas may be supplied. In addition, since etching of the silicon-containing film is started as soon as the IF₇ gas is supplied, it is preferable to quickly set the pressures and the gas flow rate to respective specified values.

In addition, heat of reaction is generated when the processing gas and the silicon film are in contact with each other. It may be considered that the heat of reaction is conducted to a metal film or a substrate by thermal conduction, which results in deterioration of characteristics of the metal film or bending of the substrate. Further, it may be considered that the temperature of the wafer 600 is out of a predetermined temperature range, which results in loss of high selectivity of the processing gas.

In addition, since the concentration of the processing gas is in proportion to an etching rate of the processing gas and the etching rate is also in proportion to the heat of reaction, heating of the metal film or substrate by the heat of reaction becomes noticeable if the etching rate is increased with an increase in the concentration of the processing gas.

Accordingly, together with the processing gas, a dilution gas is supplied into the process chamber 445 in order to decrease the concentration of the processing gas and hence suppress excessive increase in temperature by the heat of reaction. The amount of supply of the dilution gas is set to be larger than that of the processing gas.

In addition, the dilution gas may be supplied simultaneously with processing gas. Alternatively, the processing gas may be supplied after the dilution gas is supplied. When the processing gas is supplied later in this way, it is possible to prevent the processing gas with high concentration from being supplied to the wafer 600, which can result in high processing uniformity of the wafer 600. In addition, it is also possible to prevent rapid change in the temperature of the wafer 600 by the heat of reaction.

More desirably, the dilution gas is first supplied and the processing gas is then supplied after the internal pressure of the process chamber is stabilized. This can be applied to a case where the volume of the dilution gas is sufficiently larger than the volume of the processing gas, and is effective, for example in a process of controlling an etching depth. In this case, since etching is performed under a state where a pressure is stabilized, it is possible to stabilize an etching rate. As a result, it becomes easy to control the etching depth.

### (Silicon-Containing Film Removing Step S60)

When the substrate temperature, the pressure and the gas flow rate are maintained at respective predetermined values for a predetermined time, the silicon-containing film is selectively removed by a predetermined amount.

### (Denatured Layer Removing Step S70)

A denatured layer left after the removal of the silicon-containing film is removed as necessary. The removal of the denatured layer is performed, for example by supplying a removal gas. In this case, an HF gas may be introduced in the process chamber or, alternatively, an HF gas component may be generated by introducing a mixture of an IF₇ gas and an H₂ gas in the process chamber and plasmarizing the mixture. When the IF₇ gas is supplied, the silicon-containing film which may be partially left in the above-described silicon-containing film removing step can be removed. In addition, an intermediate film between the silicon-containing film and the denatured layer can be also removed. In addition, the denatured layer may be removed by supplying a gas, which is obtained by activating (plasmarizing) one or both of a rare gas such as an argon gas and a reducing gas such as a hydrogen gas, as a remover, to the wafer 600. The denatured layer can be removed with sputtering by supplying the activated rare gas to the wafer 600. In addition, the denatured layer can be deoxidized by supplying the activated hydrogen gas to the wafer 600. By supplying such an activated remover to the wafer 600, it is possible to remove the denatured layer 605a without doing damage to the SOC film 606 as a buried film.

In particular, in the case of removing a denatured layer in a trench structure having a large aspect ratio, it is effective to plasmarize (activate) the processing gas and inject the gas into the trench. In addition, since the reactivity of the HF gas is greatly influenced by the content of water in a reaction chamber atmosphere, it is effective to remove the denatured layer using the plasmarized and sufficiently activated processing gas.

### (Purging/Cooling Step S80)

After the required removing step is terminated, the supply of the processing gas is stopped and the atmosphere gas in the processing vessel 431 and process chamber 445 is exhausted. At this time, the atmosphere gas may be exhausted while flowing an inert gas for purge. In addition, as described above, since the halogen-containing gas is heavier than the purge gas, there is a possibility that the processing gas is left. Therefore, it is preferable to perform sufficient purging in order not to leave the processing gas. For example, the supply of the inert gas and the exhaust of the atmosphere gas are alternately performed. This can prevent the halogen-containing gas from being left in the process chamber or from being flown out of the process chamber. In addition, the lifter pins 413 are lifted up to separate the wafer 600 from the susceptor table 411 such that the wafer 600 is cooled to a transferable temperature.

### (Substrate Unloading Step S90)

When the wafer 600 is cooled to the transferable temperature and is ready to be unloaded from the process chamber, the wafer 600 is unloaded in the reverse order of the above-described substrate loading step S10.

### (3) Denatured Layer Removing Step

The denatured layer removing step according to this embodiment will be described in more detail below.

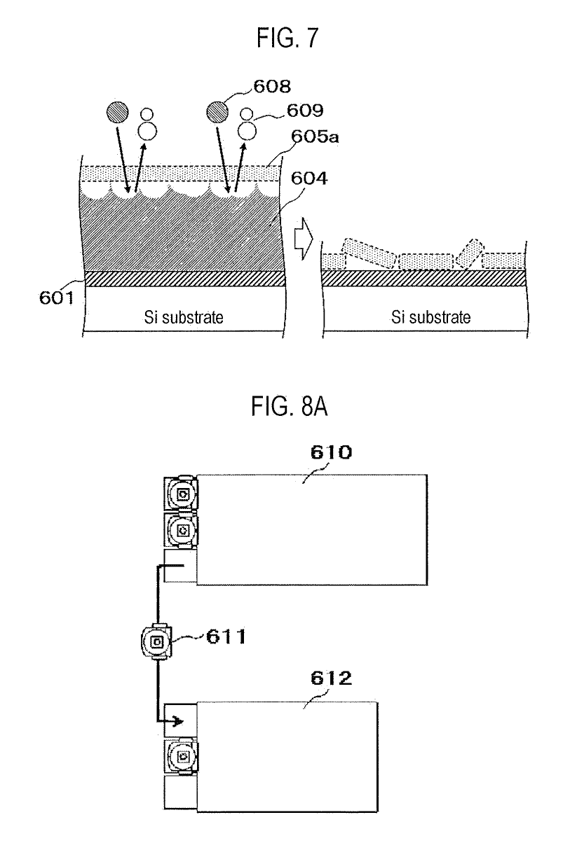

If the silicon-containing film to be removed is covered by a sufficiently thick and dense denatured layer, this layer inhibits the IF₇ gas from infiltrating into the silicon-containing film, thereby causing no silicon removal reaction. However, if the denatured layer is a thin and sparse film such as a natural oxide film, it is found that the IF₇ gas passes through the denatured layer and reacts with underlying silicon and the denatured layer is left as a residue while silicon is being removed. FIG. 7 shows the concept of this phenomenon.

In particular, since the surface of the silicon-containing film is easily naturally oxidized, if no attention is paid to removal of this natural oxide film, an unintended residue may occur after the removal of the silicon-containing film by the IF₇ gas.

In addition, although the substrate can be wet-cleaned before the removal of the silicon-containing film, since a fine structure having a high aspect ratio is exposed after the removal of the silicon-containing film, the substrate may not be wet-cleaned in many cases. An example of the phrase “fine structure having a high aspect ratio” used herein may include a pillar structure. In such a case, if a residue of the denatured layer is left after the removal of the silicon-containing film, there is a possibility that there is no way to remove the residue. For example, when the wafer 600 having an exposed fine structure having a high aspect ratio is wet-cleaned, there is a problem of pattern collapse as described above. Therefore, it is particularly important to remove the denatured layer, which is the origin of the residue, before the removal of the silicon-containing film.

Next, as different forms of substrate processing flow, cases where the substrate processing flow illustrated above with reference to FIG. 6 is divided into different elements performed at different places will be illustrated below.

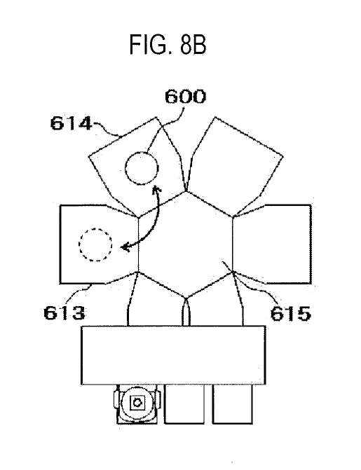

FIG. 8A illustrates another form of substrate processing flow. In this form, the denatured layer removing step S30 is first performed in a denatured layer removing device 610 and the silicon-containing film removing step S60 is then performed in a silicon-containing film removing device 612. In addition, as the denatured layer preventing step S40, a new denatured layer is prevented from occurring by storing and transferring the substrate in a vessel 611 under an inert gas atmosphere. An example of this form may include removing a denatured layer by means of a wet cleaning device and using an N₂ purge FOUP (Front Opening Unified Pod) to transfer the substrate to a device for removing the silicon-containing film. In addition, a denatured layer removing method is not limited to the wet cleaning but may be a drying process using a gas. It is to be understood by those skilled in the art that various forms, changes and additions to the denatured layer removing method and the new denatured layer preventing method are possible without departing from the spirit of the present disclosure.

FIG. 8B illustrates still another form of substrate processing flow. In this form, a cluster type substrate processing apparatus is used to connect a reaction chamber 613 for denatured layer removal and a reaction chamber 614 for silicon-containing film removal with a vacuum transfer chamber 615 in which an inert gas is purged and performs a series of processes successively. In this form, the denatured layer removing steps S30 and S70 are performed in the reaction chamber 613, the denatured layer preventing step S40 is performed in the vacuum transfer chamber 615, and the silicon-containing film removing step S60 is performed in the reaction chamber 614. Alternatively, the denatured layer removing steps S30 and S70 may be performed in their respective separate reaction chambers.

### (4) Effects of the Embodiment

According to this embodiment, one or more effects are provided as described below.

(a) In the gas etching process of using the IF₇ gas to selectively remove Si, it is possible to remove a denatured layer, which inhibits the silicon removal reaction, in advance.

(b) In addition, in the gas etching process of using the IF₇ gas to selectively remove Si, it is possible to prevent a residue attributed to a denatured layer existing on the surface of the silicon-containing film to be removed.

(c) In addition, it is possible to prevent the substrate processing apparatus from being contaminated by the residue attributed to the denatured layer.

(d) In addition, in the gas etching process of using the IF₇ gas to selectively remove Si, it is possible to prevent a residue attributed to a denatured layer existing on a place covered by the silicon-containing film to be removed.

(e) In addition, by removing the silicon-containing film with a halogen-containing gas after removing the denatured layer with a removal gas, it is possible to remove the silicon-containing film without collapsing an electrode formed on the substrate.

(f) In addition, by performing the denatured layer removing step after the silicon-containing film removing step, it is possible to remove an oxide film formed on an interface between the silicon-containing film and the electrode.

(g) Further, by using one or both of an activated rare gas and an activated reducing gas to remove the denatured layer, it is possible to remove the denatured layer without doing damage to a buried film.

### Other Embodiments of the Present Disclosure

The embodiments of the present disclosure have been described in detail. However, the present disclosure is not limited to the foregoing embodiment but may be variously modified without departing from the spirit of the present disclosure.

The present disclosure, which provides a substrate processing method and apparatus capable of selectively removing silicon while removing an unnecessary denatured layer by combining a step of removing a denatured layer existing on the surface of a silicon-containing film to be removed, a step of preventing the occurrence of a new denatured layer, and a step of removing a denatured layer existing on a place covered by the silicon-containing film to be removed, in a selective Si dry etching process using an IF₇ gas, does not limit its scope to the number of substrates to be simultaneously processed, the direction in which substrates are held, the type of dilution gas and purge gas, the cleaning method, the shape of a substrate processing chamber, a heating mechanism and a cooling mechanism, and so on.

In addition, the present disclosure is not limited to the step of dry-etching one or both of the denatured layer and the silicon-containing film formed on the substrate but may involve a step of removing (cleaning) a denatured layer and a silicon-containing film deposited within the substrate processing chamber.

In addition, although it has been illustrated in the above embodiment that the removal gas and the processing gas are used to directly remove a targeted film, the present disclosure is not limited thereto. For example, the targeted film may be removed by generating a reactant through reaction of a halogen salt with a silicon oxide film, and heating and vaporizing the reactant.

In addition, although, in the above embodiment, the denatured layer has been illustrated with the silicon oxide film formed on the silicon-containing film, the present disclosure is not limited thereto. For example, when a plasma process using hydrogen and nitrogen is performed in resist ashing, a nitride film is formed on the substrate or the surface of a film formed on the substrate. The existence of this nitride film may cause the problem as described above. To avoid this problem, it is possible to limit an amount of remaining nitride film by removing the nitride film (denatured layer) before removing the silicon-containing film.

In addition, although it has been illustrated in the above embodiment that the denatured layer formed on the mold silicon film for electrode formation is removed with a remover and the mold silicon film is removed with a processing gas, the present disclosure is not limited thereto. For example, in removing a dummy gate electrode consisting mainly of silicon, the dummy gate electrode may be removed with a processing gas after removing a natural oxide film formed on the surface of the dummy gate electrode.

Further, the present disclosure is not limited to a semiconductor device manufacturing apparatus for processing semiconductor wafers, such as the substrate processing apparatus according to this embodiment, but may be applied to an LCD (Liquid Crystal Display) manufacturing apparatus for processing glass substrates, a substrate processing apparatus such as a solar cell manufacturing apparatus, and an MEMS (Micro Electro Mechanical Systems).

### Aspects of the Present Disclosure

Hereinafter, some aspects of the present disclosure will be additionally stated.

### Supplementary Note 1

According to an aspect of the present disclosure, there is provided a substrate processing apparatus including: a processing vessel configured to accommodate a substrate including an Si-containing film on which a denatured layer is formed; a remover supplying part configured to supply a remover of the denatured layer to the substrate; a processing gas supplying part configured to supply a processing gas capable of removing the Si-containing film and containing two or more halogen elements to the substrate; and a control unit configured to control the remover supplying part and the processing gas supplying part to perform a process including: supplying the remover through the remover supplying part to the substrate, supplying the processing gas through the processing gas supplying part to the substrate, and supplying the remover through the remover supplying part to the substrate after the act of supplying the processing gas to the substrate.

### Supplementary Note 2

In the substrate processing apparatus according to Supplementary Note 1, the halogen elements are fluorine and iodine.

### Supplementary Note 3

In the substrate processing apparatus according to Supplementary Note 1 or 2, the processing gas is a gas containing one or two or more selected from a group consisting of iodine pentafluoride, iodine heptafluoride, bromine trifluoride, bromine pentafluoride, xenon difluoride and chlorine trifluoride.

### Supplementary Note 4

In the substrate processing apparatus according to any one of Supplementary Notes 1 to 3, the denatured layer is a silicon oxide film.

### Supplementary Note 5

In the substrate processing apparatus according to any one of Supplementary Notes 1 to 4, the process further includes preventing the denatured layer from occurring after the act of supplying the processing gas to the Si-containing film.

### Supplementary Note 6

In the substrate processing apparatus according to any one of Supplementary Notes 1 to 5, the process further includes preventing the denatured layer from occurring after one or both of the act of supplying the remover to the substrate and the act of supplying the processing gas to the substrate.

### Supplementary Note 7

In the substrate processing apparatus according to any one of Supplementary Notes 1 to 6, the control unit is further configured to control the remover supplying part and the processing gas supplying part to supply the processing gas after supplying the remover in the act of supplying the remover to the substrate.

### Supplementary Note 8

In the substrate processing apparatus according to any one of Supplementary Notes 1 to 7, the control unit is further configured to control the remover supplying part and the processing gas supplying part to supply the remover after supplying the processing gas in the act of supplying the processing gas to the substrate.

### Supplementary Note 9

In the substrate processing apparatus according to Supplementary Note 7, the control unit is further configured to control the remover supplying part and the processing gas supplying part to supply the processing gas to the substrate after stopping the supply of the remover in the act of supplying the remover to the substrate.

### Supplementary Note 10

In the substrate processing apparatus according to Supplementary Note 8, the control unit is further configured to control the remover supplying part and the processing gas supplying part to stop the supply of the processing gas after supplying the remover in the act of supplying the processing gas to the substrate.

### Supplementary Note 11

In the substrate processing apparatus according to any one of Supplementary Notes 1 to 10, the processing gas is generated by exciting a mixture of a halogen element-containing gas and a basic gas.

### Supplementary Note 12

In the substrate processing apparatus according to any one of Supplementary Notes 1 to 11, the remover is an activated rare gas.

### Supplementary Note 13

In the substrate processing apparatus according to Supplementary Note 12, the denatured layer is removed by being sputtered by the activated rare gas.

### Supplementary Note 14

In the substrate processing apparatus according to any one of Supplementary Notes 1 to 11, the remover is an activated reducing gas.

### Supplementary Note 15

In the substrate processing apparatus according to any one of Supplementary Notes 1 to 11, the remover is a gas containing one or more halogen elements.

### Supplementary Note 16

According to another aspect of the present disclosure, there is provided a method for manufacturing a semiconductor device, including: loading a substrate including an Si-containing film on which a denatured layer is formed, into a processing vessel; supplying a remover to the substrate in order to remove the denatured layer; supplying a processing gas containing two or more halogen elements, to the substrate in order to remove the Si-containing film; and supplying the remover to the substrate after the act of removing the Si-containing film in order to remove a residue of the denatured layer left after the act of removing the Si-containing film.

### Supplementary Note 17

In the method according to Supplementary Note 16, the halogen elements are fluorine and iodine.

### Supplementary Note 18

In the method according to Supplementary Note 16 or 17, the processing gas is a gas containing one or two or more selected from a group consisting of iodine pentafluoride, iodine heptafluoride, bromine trifluoride, bromine pentafluoride, xenon difluoride and chlorine trifluoride.

### Supplementary Note 19

In the method according to any one of Supplementary Notes 16 to 18, the denatured layer is a silicon oxide film.

### Supplementary Note 20

In the method according to any one of Supplementary Notes 16 to 19, the act of removing the denatured layer includes: supplying a removal gas including a rare gas; and activating the removal gas.

### Supplementary Note 21

In the method according to any one of Supplementary Notes 16 to 20, the act of removing the denatured layer includes: supplying a removal gas including a reducing gas; and activating the removal gas.

### Supplementary Note 22

According to any one of Supplementary Notes 16 to 21, the method further includes: preventing the denatured layer from occurring after the act of removing the Si-containing film.

### Supplementary Note 23

According to any one of Supplementary Notes 16 to 22, the method further includes: preventing the denatured layer from occurring after one or both of the act of removing the denatured layer and the act of removing the Si-containing film.

### Supplementary Note 24

In the method according to any one of Supplementary Notes 16 to 23, in the act of removing the denatured layer, the processing gas is supplied after supplying the remover.

### Supplementary Note 25

In the method according to any one of Supplementary Notes 16 to 24, in the act of removing the Si-containing film, the remover is supplied after supplying the processing gas.

### Supplementary Note 26

In the method according to Supplementary Note 24, in the act of removing the denatured layer, the act of removing the Si-containing film is performed after stopping the supply of the remover.

### Supplementary Note 27

According to another aspect of the present disclosure, there is provided a program that causes a computer to perform a process of: loading a substrate including an Si-containing film on which a denatured layer is formed, into a processing vessel; supplying a remover to the denatured layer in order to remove the denatured layer; and supplying a processing gas containing two or more halogen elements, to the Si-containing film in order to remove the Si-containing film.

### Supplementary Note 28

According to another aspect of the present disclosure, there is provided a non-transitory computer-readable recording medium storing a program that causes a computer to perform a process of: loading a substrate including an Si-containing film on which a denatured layer is formed, into a processing vessel; supplying a remover to the substrate in order to remove the denatured layer; supplying a processing gas containing two or more halogen elements, to the substrate in order to remove the Si-containing film; and supplying the remover to the substrate after the act of removing the Si-containing film in order to remove a residue of the denatured layer left after the act of removing the Si-containing film.

### Supplementary Note 29

According to another aspect of the present disclosure, there is provided a substrate including an Si-containing film on which a denatured layer is formed, the substrate being subjected to a process of: supplying a remover to the denatured layer in order to remove the denatured layer; and supplying a processing gas containing two or more halogen elements, to the Si-containing film in order to remove the Si-containing film.

### Supplementary Note 30

According to another aspect of the present disclosure, there is provided a substrate having a semiconductor device structure including a collapse prevention support part and a cylindrical electrode, in which a denatured layer is formed on an Si-containing film, the substrate being subjected to a process of: supplying a remover to the denatured layer in order to remove the denatured layer; and supplying a processing gas containing two or more halogen elements, to the Si-containing film in order to remove the Si-containing film.

### INDUSTRIAL APPLICABILITY

According to the substrate processing apparatus, the method for manufacturing a semiconductor device and the recording medium of the present disclosure, it is possible to increase a manufacturing throughput of semiconductor devices while improving the quality thereof.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a semiconductor device, comprising:
supplying a remover to the substrate including a Si-containing film on which a denatured layer is formed in order to remove the denatured layer;
supplying a processing gas containing two or more halogen elements to the substrate in order to remove the Si-containing film; and
supplying the remover to the substrate after the act of removing the Si-containing film in order to remove a residue of the denatured layer left after the act of removing the Si-containing film.

2. The method of claim 1, wherein the denatured layer is a natural silicon oxide film.

3. The method of claim 1, wherein the denatured layer is a silicon nitride film.

4. The method of claim 1, wherein the remover is an activated rare gas.

5. The method of claim 1, wherein the remover is an activated reducing gas.

6. The method of claim 1, wherein the act of removing the denatured layer includes:
supplying a mixture of an iodine heptafluoride gas and a hydrogen gas; and
activating the mixture.

7. The method of claim 1, wherein the halogen elements contained in the processing gas are fluorine and iodine.

8. The method of claim 1, wherein the processing gas is a gas containing one or two or more selected from a group consisting of iodine pentafluoride, iodine heptafluoride, bromine trifluoride, bromine pentafluoride, xenon difluoride and chlorine trifluoride.

9. The method of claim 1, further comprising: performing a denatured-layer prevention that prevents the denatured layer from occurring after one or both of the act of removing the denatured layer and the act of removing the Si-containing film.

10. A substrate processing apparatus comprising:
a processing vessel configured to accommodate a substrate including a Si-containing film on which a denatured layer is formed;
a remover supplying part configured to supply a remover of the denatured layer to the substrate;
a processing gas supplying part configured to supply a processing gas capable of removing the Si-containing film and containing two or more halogen elements to the substrate; and
a control unit configured to control the remover supplying part and the processing gas supplying part to perform a process including: supplying the remover through the remover supplying part to the substrate, supplying the processing gas through the processing gas supplying part to the substrate, and supplying the remover through the remover supplying part to the substrate after the act of supplying the processing gas to the substrate, and
wherein the control unit is connected to flow rate controllers and on-off valves for control of supply amounts of the remover and the processing gas.

11. The substrate processing apparatus of claim 10, wherein the denatured layer is a natural silicon oxide film.

12. The substrate processing apparatus of claim 10, wherein the denatured layer is a silicon nitride film.

13. The substrate processing apparatus of claim 10, wherein the remover is an activated rare gas.

14. The substrate processing apparatus of claim 10, wherein the remover is an activated reducing gas.

15. The substrate processing apparatus of claim 10, wherein the halogen elements contained in the processing gas are fluorine and iodine.

16. A non-transitory computer-readable recording medium storing a program that causes a computer to perform a process of: supplying a remover to the substrate including a Si-containing film on which a denatured layer is formed in order to remove the denatured layer; supplying a processing gas containing two or more halogen elements to the substrate in order to remove the Si-containing film; and supplying the remover to the substrate after the act of removing the Si-containing film in order to remove a residue of the denatured layer left after the act of removing the Si-containing film.
